(19) United States
(12) Patent Application Publication
(10) Pub. No.: US 2021/0265551 A1
(43) Pub. Date: Aug. 26, 2021

(54) THERMOCOUPLE CONNECTOR AND MANUFACTURING METHOD OF THE SAME

(71) Applicant: Sung Jin Techwin Co., LTD., Daejeon (KR)

(72) Inventors: Kyea Kwang LEE, Daejeon (KR); Young Jun LEE, Incheon (KR)

(21) Appl. No.: 16/305,753

(22) PCT Filed: Nov. 9, 2018
(86) PCT No.: PCT/KR2018/013660

§ 371 Date: Apr. 28, 2021

(30) Foreign Application Priority Data
Feb. 21, 2018 (KR) 10-2018-0020349
Nov. 8, 2018 (KR) 10-2018-0136931

(51) Int. Cl. H01L 35/32; H01L 35/02; H01R 13/03; H01R 4/62; H01R 13/04; H01R 13/52

(52) U.S. Cl. CPC H01L 35/32; H01L 35/02; H01R 13/5202; H01R 4/62; H01R 13/04; H01R 13/03

(57) ABSTRACT

The present inventive concept relates to a thermocouple connector and a manufacturing method of the same, the manufacturing method including forming connector pins, covering the connector pins using a glass material, the sensor electrodes including a positive sensor electrode and a negative sensor electrode respectively connected to the positive terminal and the negative terminal, the positive sensor electrode being the chromel and the negative terminal being the alumel, placing the connector pins in a center of a surrounding sealing material having a hole, filling liquid ceramic material into a space of the surrounding sealing material through the hole, sealing the hole, and solidifying the liquid ceramic material. According to the present inventive concept, the connector pin is provided by using the same kind of material as a material of the thermocouple sensor, whereby output voltage error is minimized and output voltage change due to long-term use is low.

### CROSS-REFERENCE TO RELATED APPLICATIONS

This application claims priority to and the benefit of Korean Patent Application No. 10-2018-0020349, filed on Feb. 21, 2018 and 10-2018-0136931, filed on Nov. 8, 2018, and PCT Application No PCT/KR2018/013660, filed on Nov. 9, 2018, the entire contents of which are incorporated herein by reference.

### BACKGROUND

The present inventive concept generally relates to a thermocouple connector and a manufacturing method of the same. More particularly, the present inventive concept relates to a thermocouple connector and a manufacturing method of the same, wherein a thermocouple connector pin is provided by using the same kind of material as a material of a thermocouple sensor, whereby output voltage error and output voltage change due to long use is minimized.

In general, in a thermocouple, two kinds of metal wires made of different materials are joined, and when there is temperature difference between two junctions, an electric current flows in a predetermined direction. When one side of closed circuit or a middle point of a metal wire is cut and opened, an electromotive force proportional to temperature difference between the two junctions is created, which is referred to as the Seebeck effect, and an open voltage occurring in this case is referred to as Seebeck voltage or the electromotive force.

Electrons are evenly distributed in a metal conductor and when heat is applied to one end of the conductor, the electrons move from a high-temperature side to a low-temperature side. Since concentrations of the electrons moving to the low-temperature side from junctions of two different metals are different, the electromotive force is produced.

Meanwhile, in Korean Utility Model Registration No. 20-0233139, there is disclosed a thermocouple connector as a conventional art, the thermocouple connector including an inlet part to which a thermocouple having positive/negative wires is introduced, a fixing part to which the introduced thermocouple is fixed, and an output unit to output a voltage of the introduced thermocouple, wherein the inlet part includes two holes provided thereon, each of the positive wire and the negative wire being introduced thereinto and being fixed by the fixing part.

Furthermore, in Korean Patent Application Publication No. 10-2016-0036475, there is disclosed an electric plug connector used to electrically connect an electronic device and a power unit having a receptacle connector to each other, the electric plug connector including a housing, a connector unit, and a temperature detection unit, wherein the housing includes a housing body defining a housing space and a cell facing the housing body by extending therefrom and defining a hollow space communicating with the housing space, the cell having an opening part communicating with the hollow space and being removably connected to the receptacle connector of the power unit, the connector unit includes a first part arranged in the housing space and surrounded by the housing body, a support tongue having a second part arranged in the hollow space by extending from the first part toward the opening part and a plurality of contact points provided on a surface of the second part of the support tongue, a first end part being electrically connected to the plurality of contact points, and a connector cable having a second end part facing the first end part and being electrically connected to the electronic device, and the temperature detection unit is arranged in at least one of the housing space and the hollow space to detect a temperature related to the support tongue.

However, according to the conventional technology, connector pins are provided by using different materials, whereby output voltage error is large and output voltage change is large during long-term use.

### SUMMARY

Accordingly, the present inventive concept has been made keeping in mind the above problems occurring in the related art, and the present inventive concept is intended to propose a thermocouple connector and a manufacturing method of the same, wherein a connector pin is provided by using the same kind of material as a material of a thermocouple sensor, whereby output voltage error is minimized and output voltage change due to long use is low.

In order to achieve the above object, according to one aspect of the present inventive concept, there are provided a thermocouple connector and a manufacturing method of the same, a material of each of connector pins of the thermocouple connector being the same kind of material as a material of a thermocouple sensor, the manufacturing method including: forming the connector pins provided by using a chromel in a positive terminal thereof and by using an alumel in a negative terminal thereof, wherein a surrounding sealing material of the thermocouple connector is a metal material and a sealing material of a portion surrounding the connector pin positioned at a middle portion of the thermocouple connector is a glass material, and surroundings of each of connector pin insertion holes of a cable combining with the thermocouple connector are sealed by ceramic sealing, and an empty space of the thermocouple connector is filled with sealing materials.

Accordingly, according to the present inventive concept, the connector pin is provided by using the same kind of material as a material of the thermocouple sensor, whereby output voltage error is minimized and output voltage change due to long-term use is low.

### BRIEF DESCRIPTION OF THE DRAWINGS

FIG. 1 is a view of a thermocouple sensor of the present inventive concept;

FIG. 2 is a detailed view of a thermocouple connector of the present inventive concept;

FIG. 3 is a view of a conventional defective male thermocouple connector;

FIG. 4 is a view of the male thermocouple connector of the present inventive concept;

FIG. 5 is a front view of the male thermocouple connector of the present inventive concept;

FIG. 6 is a view of the female thermocouple connector of the present inventive concept;

FIG. 7 is a detailed view of the female thermocouple connector of the present inventive concept;

FIG. 8 is a graph of output voltage change due to long-term use;

FIG. 9 is a graph of tolerance measurement result according to temperature; and

FIG. 10 is a cross sectional view of male thermocouple connector showing that when a large space part in which an alumel terminal, a chromel terminal, and a sensor electrode of the male thermocouple connector of the present inventive concept are connected to each other is provided, a hole is formed through a surface of the male thermocouple connector, a sealing material such as a liquid ceramic is introduced into the large space part in a liquid state, and the hole is sealed.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

The present inventive concept relates to a thermocouple connector and a manufacturing method of the same, and a material of each of connector pins 10 of the thermocouple connector 100 is the same kind of material as a material of a thermocouple sensor.

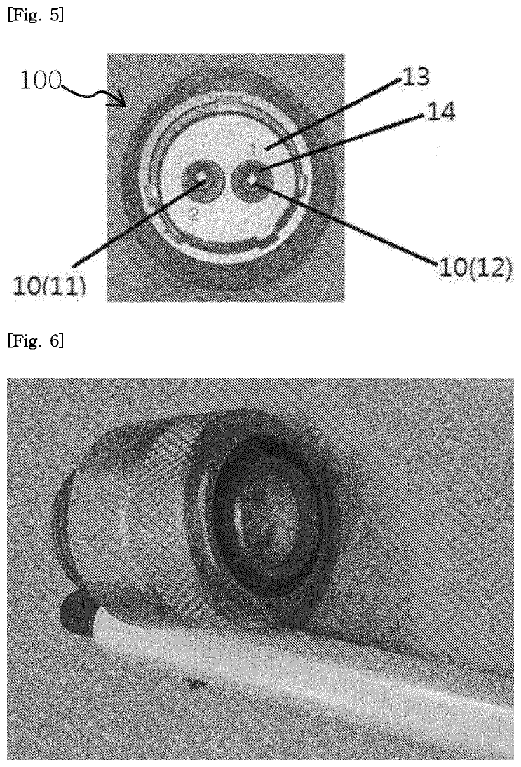

Referring to FIG. 5, a positive terminal 11 of the male thermocouple connector pin 10 is provided by using a chromel and a negative terminal 12 thereof is provided by using an alumel.

A surrounding sealing material 13 of the male thermocouple connector 100 is a metal material and a cover material 14 of a portion surrounding the connector pin 10 positioned at a middle portion of the male thermocouple connector is a glass material.

Surroundings 22 of each of connector pin insertion holes 21 of a cable 20 of the female thermocouple connector 200 combining with the male thermocouple connector 100 are sealed by ceramic sealing, and an empty space of the male thermocouple connector 100 is filled with sealing materials.

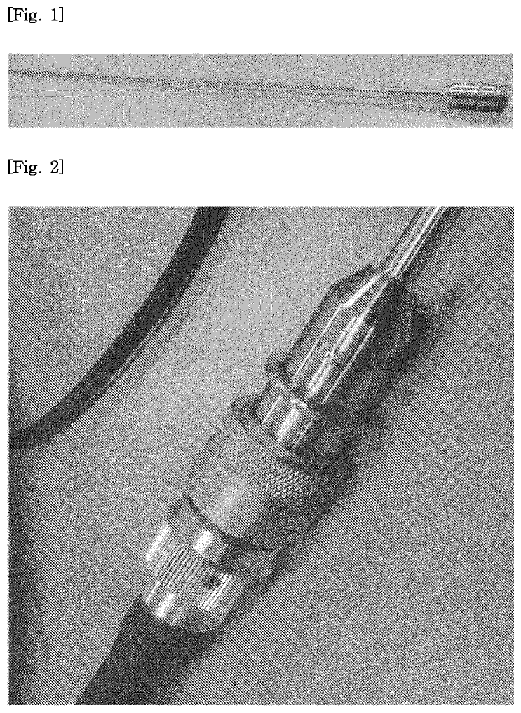

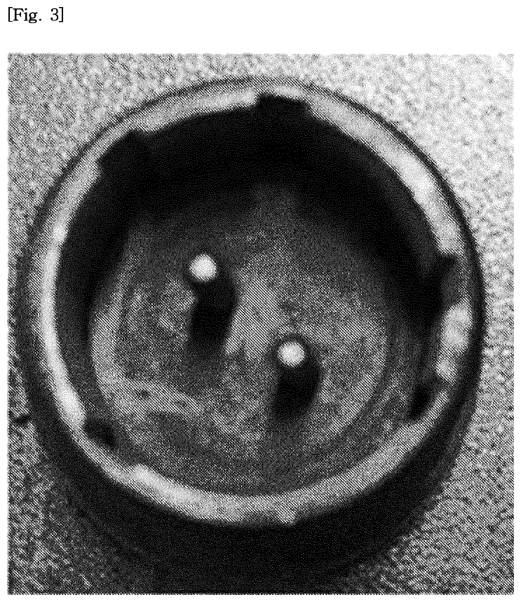

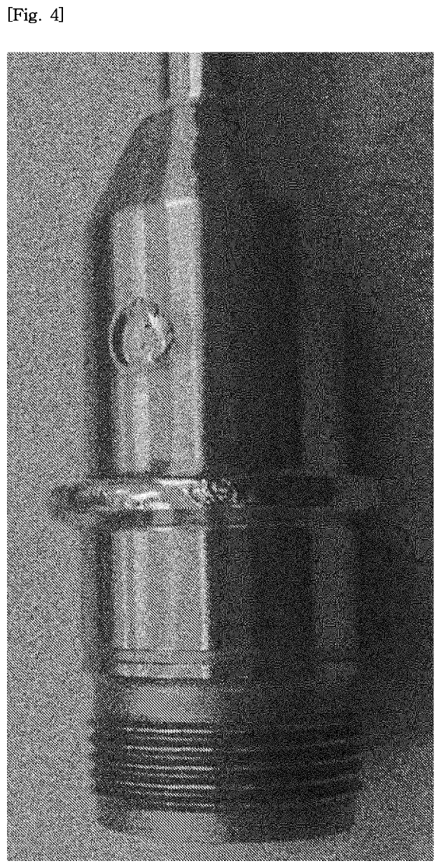

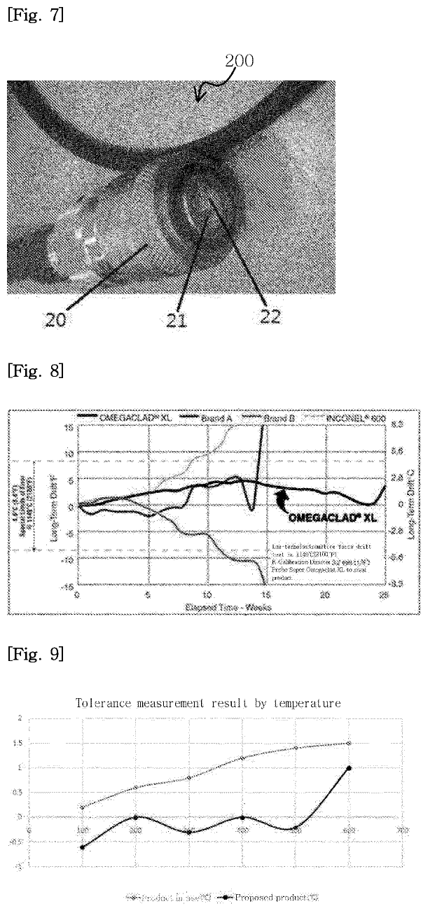

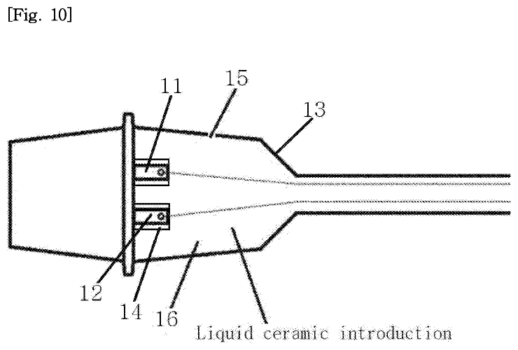

Hereinafter, the present inventive concept will be described in detail with reference to the accompanying drawings. FIG. 1 is a view of the thermocouple sensor of the present inventive concept; FIG. 2 is a detailed view of the thermocouple connector of the present inventive concept; FIG. 3 is a view of a conventional defective thermocouple connector; FIG. 4 is a view of the male thermocouple connector of the present inventive concept; FIG. 5 is a front view of the male thermocouple connector of the present inventive concept; FIG. 6 is a view of the female thermocouple connector of the present inventive concept; FIG. 7 is a detailed view of the female thermocouple connector of the present inventive concept; FIG. 8 is a graph of output voltage change due to long-term use; FIG. 9 is a graph of tolerance measurement result according to temperature; and FIG. 10 is a cross sectional view of the male thermocouple connector showing that when a large space part in which an alumel terminal, a chromel terminal, and a sensor electrode of the thermocouple connector of the present inventive concept are connected to each other is provided, a hole is formed through a surface of the male thermocouple connector, a sealing material such as a liquid ceramic is introduced into the large space part in a liquid state, and the hole is sealed.

The present inventive concept relates to the thermocouple connector, wherein the connector pin 10 of the male thermocouple connector 100 is provided by using the same kind of material as a material of the thermocouple sensor.

In addition, the positive terminal 11 of the male thermocouple connector pin 10 is provided by using the chromel, and the negative terminal 12 thereof is provided by using the alumel.

Furthermore, the surrounding sealing material 13 of the male thermocouple connector 100 is the metal material and the cover material 14 of a portion surrounding the connector pin 10 positioned at the middle portion of the male thermocouple connector 100 is a glass material which is highly resistant to temperature.

Additionally, surroundings 22 of each of the connector pin insertion holes 21 of the cable 20 of the female thermocouple connector 200 combining with the male thermocouple connector 100 are sealed by the ceramic sealing so as not to be deformed by vibration.

According to the present inventive concept, the material of each of the connector pins of the male thermocouple connector 100 is the chromel in the positive terminal thereof and the alumel in the negative terminal thereof instead of conventional Cu/Gold plating.

That is, the same kind of material as the material of the thermocouple sensor is used in each of the positive and negative terminals of the male thermocouple connector 100 so as to minimize output voltage error.

According to the present inventive concept, since Omegaclad XL is used as a sheath, output voltage change due to long-term use is low compared to when Inconel is used as a sheath.

Except for the above-mentioned points, like the conventional inventive concept, a response speed of the present inventive concept is within 2.5 second and output precision thereof is ±0.4% for exhaust gas type thermocouples.

TABLE 1

| | | Measurement result by | | | |
|---|---|---|---|---|---|
| | | temperature (Tolerance) | | | |
| | | Temper- | Product | Proposed | |
| International | | ature (° | in use(° | product(° | Test |
| standard | Pass Criteria | C.) | C.) | C.) | result |
| ASTME230 | 0~1250° | 100 | +0.2 | −0.6 | OK |
| ANSIMC96.1 | C. ± 1.1° | 200 | +0.6 | 0 | OK |
| | C. or 0.4% | 300 | +0.8 | −0.3 | OK |
| | | 400 | +1.2 | 0 | OK |
| | | 500 | +1.4 | −0.2 | OK |
| | | 600 | +1.5 | +1.0 | OK |
| IEC60584- | −40° | 100 | +0.2 | −0.6 | OK |
| 2JIS | C.~375° | 200 | +0.6 | 0 | OK |
| C1602 | C.: ± 1.5° C. | 300 | +0.8 | −0.3 | OK |
| | 375° | 400 | +1.2 | 0 | OK |
| | C.~1000° | 500 | +1.4 | −0.2 | OK |
| | C.: ± 0.4% | 600 | +1.5 | +1.0 | OK |

Table 1 shows the comparative advantage of the present inventive concept. According to the present inventive concept, the material of the connector pin 10 of the male thermocouple connector 100 is the same kind of material as the material of the thermocouple sensor.

That is, like the thermocouple sensor, the positive terminal 11 of the connector pin 10 of the male thermocouple connector 100 is formed by using the chromel and the negative terminal 12 thereof is formed by using the alumel. The thermocouple sensor connected to a rear portion of the connector pin of the male thermocouple connector 100 is provided in a stainless tube.

Meanwhile, the surrounding sealing material 13 of the male thermocouple connector 100 is the metal material and the cover material 14 of a portion surrounding the connector pin 10 positioned at the middle portion of the male thermocouple connector 100 is a glass material, and the metal material and the glass material are concentrically formed. A portion having the configuration is referred to as a glass to metal portion.

According to the conventional art, a sealing material of the stainless tube connected to the rear portion of a connector pin is a rubber, which decreases durability and causes many problems.

Meanwhile, since a rear part of the glass to metal portion on which the metal material and the glass material are concentrically provided in the empty space of the male thermocouple connector 100 of the present inventive concept includes the large space part in which the alumel terminal, the chromel terminal, and the sensor electrode are connected to each other, the hole 15 is formed through the surface of the surrounding sealing material 13 of the male thermocouple connector 100, the sealing material 16 such as a liquid ceramic is introduced into the large space part in a liquid state, and the hole is sealed. When the liquid sealing material 16 is solidified after a predetermined hour, an alumel wire and a chromel wire are securely fixed not to move and thus are configured to be resistant to vibration

In addition, surroundings of the connector pin insertion hole 21 of the cable 20 of the female thermocouple connector 200 combining with the male thermocouple connector 100 are sealed by the ceramic sealing so as to form a ceramic sealing part, whereby sealing of the surroundings is secured.

Hereinafter, a manufacturing method of the thermocouple connector will be provided.

The method includes forming the connector pins provided by using a chromel in a positive terminal thereof and by using an alumel in a negative terminal thereof, covering the connector pins using a glass material to surround the connector pins, connecting sensor electrodes to the connector pins, the sensor electrodes including a positive sensor electrode and a negative sensor electrode respectively connected to the positive terminal and the negative terminal, the positive sensor electrode being the chromel and the negative terminal being the alumel, placing the connector pins surrounded by the glass material and connected to the connecting sensor electrodes in a center of a surrounding sealing material having a hole, the surrounding sealing material being a metal, filling liquid ceramic material into a space of the surrounding sealing material through the hole, sealing the hole, and solidifying the liquid ceramic material.

According to an embodiment of the present inventive concept, like the connector pin, a middle portion surrounding a lower terminal of each of the connector pin insertion holes of the cable 20 of the female thermocouple connector 200 is provided by using the glass material and a portion surrounding the middle portion is provided concentrically to the middle portion by using the metal material so as to support the connector pin.

Accordingly, according to the present inventive concept, the connector pin of the male thermocouple connector is provided by using the same kind of material as the material of the thermocouple sensor, whereby the output voltage error is minimized and output voltage change due to long-term use is low, and resistance to vibration is obtained due to a ceramic sealing material introduced into the large space part.

1-2. (canceled)

3. A thermocouple connector comprising a male thermocouple connector and a female thermocouple connector: the male thermocouple connector comprising:
connector pins provided by using a chromel in a positive terminal thereof and by using an alumel in a negative terminal thereof,
a cover material surrounding the connector pin positioned at a middle portion of the male thermocouple connector, the cover material being a glass material.
sensor electrodes connected to the connector pins, respectively, and
a surrounding sealing material surrounding the connector pins and the sealing material, the surrounding sealing material including a metal material,
wherein a material of each of the thermocouple connector pins of the male thermocouple connector is the same as a material of each of the sensor electrode connected thereto.

4. The thermocouple connector of claim 3, further comprises a sealing material filling a space in the surrounding sealing material, the sealing material being a ceramic material.

5. A manufacturing method of a thermocouple connector, the manufacturing method comprising:
forming connector pins provided by using a chromel in a positive terminal thereof and by using an alumel in a negative terminal thereof;
covering the connector pins using a glass material to surround the connector pins;
connecting sensor electrodes to the connector pins, the sensor electrodes including a positive sensor electrode and a negative sensor electrode respectively connected to the positive terminal and the negative terminal, the positive sensor electrode being the chromel and the negative terminal being the alumel;
placing the connector pins surrounded by the glass material and connected to the connecting sensor electrodes in a center of a surrounding sealing material having a hole, the surrounding sealing material being a metal;
filling liquid ceramic material into a space of the surrounding sealing material through the hole;
sealing the hole; and
solidifying the liquid ceramic material.
